(19) United States
(12) Patent Application Publication
(10) Pub. No.: US 2009/0296441 A1
(43) Pub. Date: Dec. 3, 2009

(54) Semiconductor Power Switch

(75) Inventors: Michael Klemt, Muenchen (DE); Nils Krumme, Feldafing (DE)

Correspondence Address: DAFFER MCDANIEL LLP, P.O. BOX 684908, AUSTIN, TX, 78768, US

(73) Assignee: SCHLEIFRING UND APPARATEBAU GMBH, Fuerstenfeldbruck (DE)

(21) Appl. No.: 12/435,524

(22) Filed: May 5, 2009

(30) Foreign Application Priority Data
May 6, 2008 (EP) 08103832.5

(51) Int. Cl. H02M 7/537; H03K 17/60

(52) U.S. Cl. 363/131; 327/482

(57) ABSTRACT

A semiconductor power switch comprises at least a first IGBT and a second IGBT. The collectors of the first and second IGBTs are connected to each other, and the emitters of the first and second IGBTs are connected to each other. The first IGBT is an IGBT type with a comparatively low collector-emitter on-voltage and a comparatively high turn-on or turn-off switching energy. In contrast thereto, the second IGBT is an IGBT type with a comparatively high collector-emitter on-voltage and a comparatively low turn-on or turn-off switching energy. Both IGBTs receive gate signals from a control circuit for switching the power switch on during a first time interval and switching the power switch off during a second time interval. The control circuit is designed to supply an on-signal to the second IGBT during the whole first time interval and another on-signal to the first IGBT during only a part of the first time interval, which is less than the whole.

### PRIORITY CLAIM

The present application claims priority to European Patent Application No. 08103832.5 filed on May 6, 2008.

### BACKGROUND OF THE INVENTION

1. Field of the Invention

The invention relates to a semiconductor power switch, based on Insulated Gate Bipolar Transistors (IGBTs), and a related power converter.

2. Description of the Related Art

Power converters used, for example, as DC-DC converters, are disclosed in U.S. Pat. No. 7,333,348. This patent discloses a full bridge switching circuit for driving a resonance circuit comprising a series inductance, a series capacitor, and a transformer. The full bridge switching circuit comprises Metal Oxide Semiconductor Field Effect Transistor (MOSFET) switches. For improving switching efficiency, the MOSFET switches are turned on and off during current zero-crossings of the resonance circuitry. For increasing the power level, the MOSFETs used in the switching circuit must be replaced by more powerful IGBTs. Furthermore, zero-crossing switching makes control of power flow very difficult.

Another power converter, which uses zero voltage switching technology to increase efficiency, is disclosed in U.S. Pat. No. 7,339,801. This circuit offers better control of power flow, but is difficult to implement using IGBTs for higher power levels. For increasing switching power while maintaining good switching characteristics, a combination of IGBTs and FETs is disclosed in U.S. Pat. No. 4,901,127.

Another approach for improving switching characteristics is the monolithic integration of punch-through IGBTs and non-punch-through IGBTs.

A specific application of power converters for contactless power transfer between rotating parts is disclosed in U.S. Pat. No. 7,197,113.

### BRIEF SUMMARY OF THE INVENTION

The following description of the objective of the disclosure provided herein and the description of embodiments of a power switch is not to be construed in any way as limiting the subject matter of the appended claims.

A general objective of the disclosure set forth herein is to provide a power switch for power converters, a power converter using such a switch, and a rotating power transmission device having increased efficiency and higher power capability.

An embodiment of a semiconductor power switch comprises at least one first Insulated Gate Bipolar Transistor (IGBT) having a collector and an emitter, and at least one second IGBT having a collector and an emitter, wherein the collectors of the IGBTs are connected to each other, and the emitters of the IGBTs are connected to each other. The at least one first IGBT may be an IGBT type with a comparatively low collector-emitter on-voltage and a comparatively high turn-on or turn-off switching energy. Conversely, the at least one second IGBT may be an IGBT type with a comparatively high collector-emitter on-voltage and a comparatively low turn-on or turn-off switching energy. A control circuit is included for supplying gate signals to the IGBTs for switching the power switch on during a first time interval, and switching the power switch off during a second time interval. In this embodiment, the control circuit is designed to supply an on-signal to the second IGBT during a whole of the first time interval, and an on-signal to the first IGBT during only parts of the first time interval.

Another embodiment of a semiconductor power switch comprises at least one first IGBT having a collector and an emitter, and at least one second IGBT having a collector and an emitter, wherein the collectors of the IGBTs are connected to each other, and the emitters of the IGBTs are connected to each other. The at least one first IGBT is an IGBT type with a comparatively low collector-emitter on-voltage and a comparatively high turn-on or turn-off switching energy. Conversely, the at least one second IGBT is an IGBT type with a comparatively high collector-emitter on-voltage and a comparatively low turn-on or turn-off switching energy. In addition, a control circuit is included for supplying gate signals to the IGBTs for switching the power switch on during a first time interval, and switching the power switch off during a second time interval. In this embodiment, the control circuit is designed to supply an on-signal to the at least one second IGBT, and an on-signal to the at least one first IGBT. Specifically, the control circuit is designed so that the on-signal supplied to the at least one first IGBT ends at a time before the on-signal supplied to the at least one second IGBT ends, and with a predetermined first time difference of at least a turn-off time of the at least one first IGBT.

Embodiments of the semiconductor power switch described herein may be used in power generators and contactless rotary joints. For example, a power generator is provided herein for generating an AC signal which can be coupled via a transformer, using a semiconductor power switch as described above. In addition, a contactless rotary joint is provided herein having a rotating power transformer and at least a semiconductor power switch as described above for generating an AC signal which can be coupled via a transformer.

### BRIEF DESCRIPTION OF THE DRAWINGS

In the following the invention is described by way of example without limitation of the general inventive concept with the aid of embodiments and with reference to the drawings.

FIG. 1 shows an embodiment of a power converter.

FIG. 2 shows an embodiment of a semiconductor power switch.

FIG. 3 shows another embodiment of a power converter.

FIG. 4 shows a simple power converter as known from prior art.

FIG. 5 shows a timing diagram of the power converter shown in FIG. 1.

FIG. 6 shows a positive half wave of the timing diagram of FIG. 5 in more detail.

FIG. 7 shows a timing diagram of an alternative embodiment of a power converter.

FIG. 8 shows a detailed diagram of the voltage curve shown in FIG. 6.

FIG. 9 shows a plot of measurements made on the power converter shown in FIG. 1.

FIG. 10 shows the plot of FIG. 9 on a different scale.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF PREFERRED EMBODIMENTS

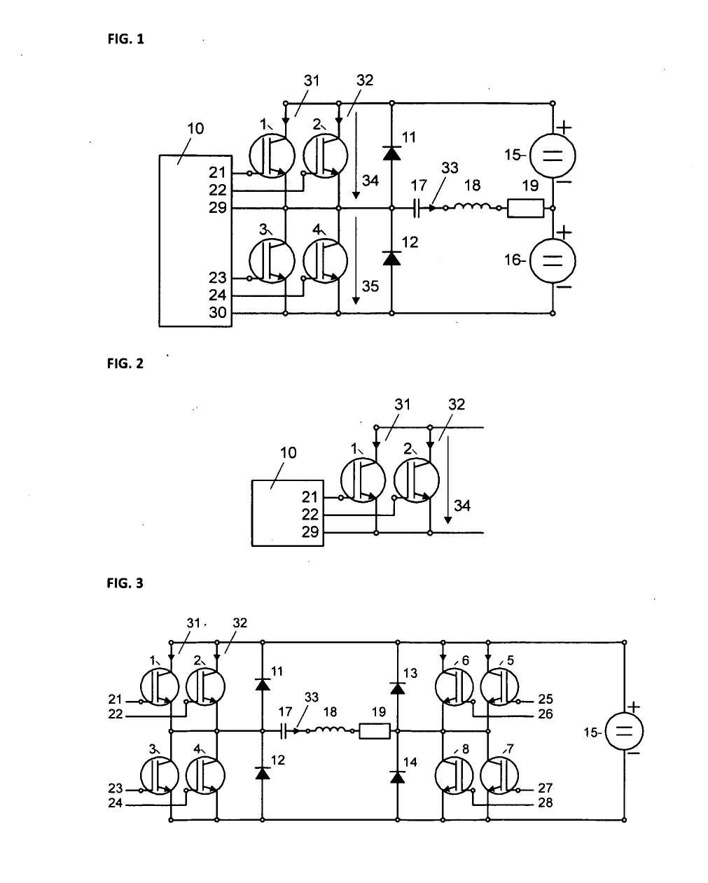

An embodiment of a power converter is disclosed in FIG. 1. The power converter shown in FIG. 1 comprises a first pair of Insulated Gate Bipolar Transistors (IGBTs) consisting of IGBT 1 and IGBT 2, and a second pair of IGBTs consisting of IGBT 3 and IGBT 4. Within each pair of IGBTs, the collectors are connected together and the emitters are connected together. A pair of serially coupled diodes 11, 12 is connected in parallel with each of the IGBT pairs, but with reversed polarity (i.e., current flow through the diodes is in an opposite direction to the current flow through the IGBT pairs).

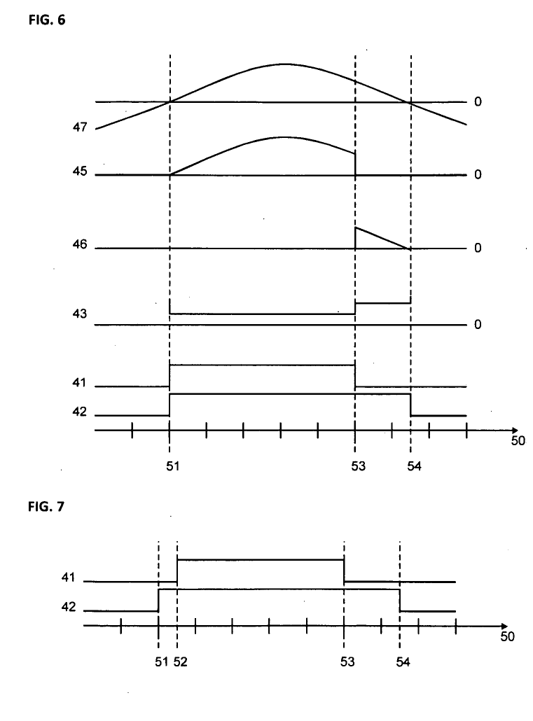

In a preferred embodiment, each pair of IGBTs includes two different types of IGBT. For example, IGBT 1 and IGBT 3 may each be an IGBT type with a comparatively low collector-emitter on-voltage and a comparatively high turn-on or turn-off switching energy. Conversely, IGBT 2 and IGBT 4 may each be an IGBT type with a comparatively high collector-emitter on-voltage and a comparatively low turn-on or turn-off switching energy. The benefits of including two different types of IGBTs within each pair of IGBTs will be described below in reference to the timing diagrams of FIGS. 5 and 6.

Power is supplied to the power converter of FIG. 1 by a series circuit comprising a first DC power source 15 and a second DC power source 16. Such a power source typically is the line input from an AC power line rectified by a bridge rectifier and optionally filtered by a parallel capacitor. The positive output from the first DC power source 15 is connected to the collectors of the first pair of IGBTs (1, 2). The negative output from the first power source 15 is connected to the positive output from the second DC power source 16. The negative output from the second DC power source 16 is connected to the emitters of the second pair of IGBTs (3, 4). The emitters of the first pair of IGBTs (1, 2) are connected to the collectors of the second pair of IGBTs (3, 4) at line 29. Furthermore, this line is connected to the diodes 11 and 12 and a resonant load circuit comprising a capacitor 17, an inductance 18 and a resistive load 19, which in turn, is connected to the center connection between the negative output of the first DC power source 15 and the positive output of the second DC power source 16.

The load circuit shown in FIG. 1 is only one exemplary embodiment of a load circuit, which may be used within the power converter of FIG. 1. A load circuit comprising series resonance circuitry is shown in FIG. 1 for purposes of simplifying the explanation of the operation of the circuit. It is understood, however, that other load circuits according to the state of the art may be used in place of the one shown. In addition, the sequence of the parts (17, 18, 19) shown in FIG. 1 may be exchanged, as this has no effect on the operation of the circuit. In some embodiments, a transformer may be used instead of the series inductance 18.

A control circuit 10 is included for providing the gate voltages (or “gate signals”) to the gates 21, 22 of the first pair of IGBTs (1, 2) and to the gates 23, 24 of the second pair of IGBTs (3, 4). The gate voltage supplied to the first pair of IGBTs is referred to the emitter line 29 of the first pair of IGBTs, while the gate voltage supplied to the second pair of IGBTs is referred to the emitter line 30 of the second pair of IGBTs. The current 31 flowing into the first IGBT 1, the current 32 flowing into the second IGBT 2, the load current 33, the voltage 34 across the first pair of IGBTs and the voltage 35 across the second pair of IGBTs shown in FIG. 1 will be described in more detail below.

An embodiment of a semiconductor power switch is shown in FIG. 2. Unlike the power converter shown in FIG. 1, the power switch shown in FIG. 2 includes only one pair of IGBTs (IGBT 1 and IGBT 2) with the emitters and the collectors connected in parallel. Although a control circuit 10 is included in FIG. 2, the diodes, resonant load circuit and DC power circuit are not included within the power switch of FIG. 2. The control circuit 10 shown in FIG. 2 supplies a first gate signal 21 to IGBT 1 and a second gate signal 22 to IGBT 2, both signals referring to the emitter line 29 of the parallel circuit. The current 31 flowing into the first IGBT 1, the current 32 flowing into the collector of the second IGBT 2, and the voltage 34 across the collectors and emitters of the IGBTs shown in FIG. 2 will be described in more detail below.

Another embodiment of a power converter is shown in FIG. 3. Here, a full H-bridge is shown with four pairs of IGBTs: the first pair consisting of IGBTs 1 and 2, the second pair consisting of IGBTs 3 and 4, the third pair consisting of IGBTs 5 and 6, and the fourth pair consisting of IGBTs 7 and 8. Each pair of IGBTs is coupled in parallel with one freewheeling diode 11, 12, 13, 14, whose polarity is oriented in the reverse direction. In addition, series resonance and load circuit elements (i.e., capacitor 17, inductance 18, and load resistor 19) are provided between the first and second pair of IGBTs and the third and fourth pairs of IGBTs. The resonant load circuit is fed by a single DC power source 15 having a positive output connected to the collectors of the first and third pairs of IGBTs, and a negative output connected to the second and fourth pairs of IGBTs.

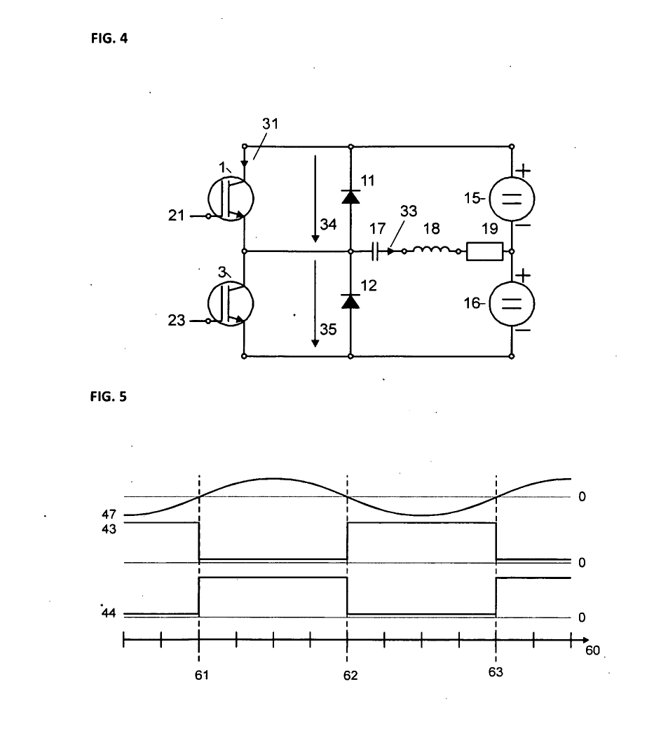

A conventional power converter is shown in FIG. 4. Unlike the present embodiments, which include at least one pair of parallel coupled IGBTs (e.g., IGBTs 1 and 2, as shown in FIGS. 1-3), the conventional power converter shown in FIG. 4 includes only one pair of serially coupled IGBTs (1, 3).

In FIG. 4, the emitter of IGBT 1 is connected to the collector of IGBT 3. The emitter of IGBT 3 is connected to the negative output of DC power source 16. The collector of IGBT 1 is connected to the positive output of DC power source 15. The negative output of DC power source 15 and the positive output of DC power source 16 are connected together at a center point. Diodes 11 and 12 are connected in parallel with, but with reversed polarity to, the pair of IGBTs 1 and 3. A load circuit, comprising a serially coupled capacitor 17, inductance 18, and load resistor 19, is connected between the emitter of IGBT 1, the collector of IGBT 3, and the center point between the two DC power sources 15, 16.

FIG. 5 shows a timing diagram of a push-pull stage of the power converter shown in FIG. 1. Line 47 shows the timing diagram of the load current 33 flowing through the series resonant circuit (17, 18, 19) in resonance condition. As shown in FIG. 5, the load current 33 has an approximately sinusoidal wave form with changing positive and negative polarity. Curve 43 shows the timing of the voltage 34 between the collectors and emitters of the first pair of IGBTs 1 and 2. Curve 44 shows the voltage 35 between the collectors and emitters of the second pair of IGBTs 3 and 4. The timing intervals between the individual ticks on the time axis 60 may be, for example, 5 microseconds (μs). Accordingly, the positive half wave occurring between the timing marks 61 and 62 is 20 μs, while the full period occurring between the timing marks 61 and 63 is 40 μs.

When the load current 33 (designated as curve 47) is positive, e.g., during a first time interval between the times 61 and 62, the voltage 34 across the first pair of IGBTs is zero, and the voltage 35 across the second pair of IGBTs is approximately equal to the sum of the voltages of the first DC power source 15 and the second DC power source 16. This is because the emitters of the first pair of IGBTs are connected to the positive output of DC power source 15 during the first time interval. During that time, the full voltage supplied by DC power sources 15 and 16 is applied across the second pair of IGBTs. As a result, the first pair of IGBTs is placed in a conducting (on) state for switching the power switch, while the second pair of IGBTs is placed in a high impedance (off) state.

The opposite is true during times when the load current 33 is negative. During a second time interval shown, e.g., between times 62 and 63, the negative load current illustrated in FIG. 5 causes the voltage 35 across the second pair of IGBTs to be zero, and the voltage 34 across the first pair of IGBTs to be approximately equal to the sum of the voltages of the first DC power source 15 and the second DC power source 16. This places the first pair of IGBTs in a high impedance (off) state and the second pair of IGBTs in a conducting (on) state for performing the switching action.

FIG. 6 illustrates the timing diagram shown in FIG. 5 in more detail. Again, the timing of the load current 33 is shown in curve 47. However, as the negative half wave is very similar, only the timing of a positive half wave is illustrated in FIG. 6. In other words, FIG. 6 illustrates the timing of the switching operation performed by the first pair of IGBTs (1, 2) during times in which the load current 33 is positive. When the load current 33 is negative, as shown in the negative half wave of FIG. 5, switching is performed by the second pair of IGBTs (3, 4) instead of the first pair of IGBTs (1, 2).

In the timing diagram of FIG. 6, curve 41 shows the timing of the voltage between first IGBT gate 21 and the emitter line 29, while curve 42 shows the voltage between the second IGBT gate 22 and the emitter line 29. The gate voltages (21, 22) applied to the first and second IGBTs are selected so that the IGBTs can be switched on or off, as required. Typical gate voltages for switching on IGBTs are in the range of 8V to 40V, while the off-voltages are in a range of 1V to −40V. In FIG. 6, curve 43 shows the voltage 34 between the collectors and emitters of the first pair of IGBTs (1, 2); curve 45 shows the current flow through IGBT 1; and curve 46 shows the current flow through IGBT 2.

As shown in FIG. 6, IGBT 1 and IGBT 2 receive their on gate signals 41, 42 at the same time. This occurs at a first zero-crossing of the load current 33 (curve 47), which occurs at the time mark 51 on the time axis 50. As noted above, IGBT 1 is preferably an IGBT type with a comparatively lower collector-emitter on-voltage and a comparatively higher switching energy than IGBT 2. This causes the turn-on delay time and the rise time of IGBT 1 to be longer than the turn-on delay time and the rise time of IGBT 2, resulting in a longer switch-on delay for IGBT 1. The time difference between the switch-on delay times of IGBT 1 and IGBT 2 is very small, and thus, is not displayed in the diagram of FIG. 6.

If the switch-on delay time of IGBT 1 is longer than that of IGBT 2, IGBT 1 will carry the switching current with its lower switching losses (as shown in curve 45), while IGBT 2 starts carrying the load current later (as shown in curve 46). This is described in more detail below. Although not specifically illustrated in FIG. 6, the power switch described herein would also work if IGBTs 1 and 2 were switched at exactly the same time, or if IGBT 1 was switched before IGBT 2. However, such embodiments would result in higher switching losses.

The switching operation performed by the first pair of IGBTs will now be described in greater detail with reference to the curves 43, 45 and 46 shown in FIG. 6. As noted above, curve 43 shows the voltage 34 between the collectors and emitters of the first pair of IGBTs (1, 2). Since the full voltage curve for the case that the IGBTs are open is typically several hundred volts, the illustrated curve 43 is truncated and only a voltage in a range of some volts is shown in FIG. 6.

When the IGBTs 1 and 2 are switched on at time 51, the voltage 34 across the first pair of IGBTs drops to a comparatively low value corresponding to the low collector-emitter on-voltage of IGBT 1, causing IGBT 1 and IGBT 2 to be in a conductive (on) state. As the first IGBT 1 has a significantly lower collector-emitter on-voltage than the second IGBT 2, the first IGBT 1 will carry most of the load current (shown in curve 45 which shows the collector current 31 of the first IGBT), resulting in lower losses during the conductive phase.

At a later time 53, some period preceding the load current 33 zero crossing time 54, IGBT 1 is switched off by switching the gate voltage 21 of IGBT 1 to a low level (e.g., close to zero volts or even some negative value). When IGBT 1 is switched off, the current through IGBT 1 goes to zero, as shown in curve 45, while the current starts flowing through IGBT 2, as shown in curve 46. As IGBT 2 has a higher collector-emitter on-voltage than IGBT 1, the voltage 34 across the first pair of IGBTs increases, for example, from 1.7 volts to 3.4 volts, as shown in curve 43.

When the load current 33 crosses the zero-crossing (according to curve 45) at time 54, IGBT 2 is switched off by setting the gate signal 22 to zero. At this time, IGBT 2 performs the switching action. The switching action is performed with low switching losses due to the comparatively low turn-on or turn-off switching energy of IGBT 2.

From FIG. 6, it is clear that the combination of two different types of IGBTs together with the stacked timing of the IGBTs enables the positive features of the two IGBTs, i.e. low loss during the conductive phase and low switching losses, to be combined. According to various embodiments disclosed herein, the stacked timing of switching the IGBTs may be applied for switching the load on, or off, or both.

An alternative embodiment of the switching operation is shown in the timing diagram of FIG. 7. As in the previous timing diagrams, curve 41 shows the gate voltage 21 applied to IGBT 1, and curve 42 shows the gate voltage applied to IGBT 2. In the timing diagram of FIG. 7, the gate voltage 21 applied to IGBT 1 (shown in curve 41) is switched on, with some time delay between times 51 and 52, after the gate voltage 22 is applied to IGBT2. This enables IGBT 2 to initiate the switching action at time 51, and IGBT 1 to take over the current after the first IGBT is switched on at time 52.

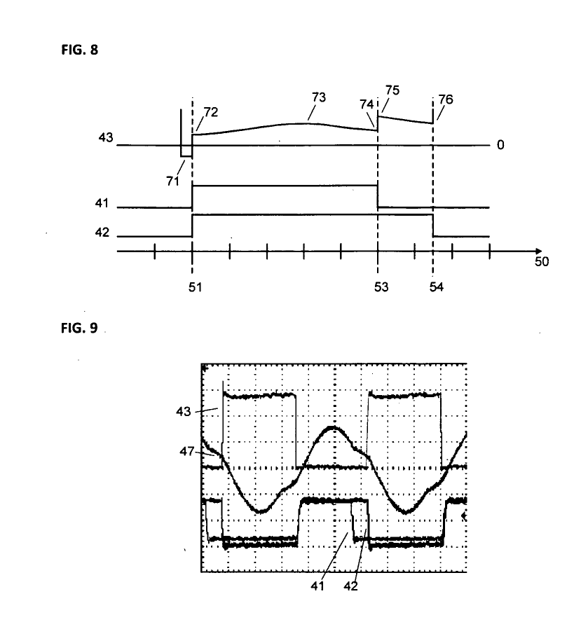

The voltage 34 between the collectors and emitters of IGBTs 1 and 2 is shown in more detail in the curve 43 shown in FIG. 8. As before, the gate voltage 22 applied to IGBT 2 is shown in curve 42 and the gate voltage 21 applied to IGBT 2 is shown in curve 41.

As shown in FIG. 8, the load current 33 zero-crossing occurs briefly before marker 51 at the switching on time of the first pair of IGBTs. Before the zero-crossing occurs at time 51, the load current is positive. However, since the first pair of IGBTs is in an off-state, diode 11 carries the whole load current 33, resulting in a slightly negative voltage 71 across the IGBTs (due, e.g., to the reverse polarity of diode 11). When the IGBTs switch on and take over the load current at time 51, the voltage 34 shown in curve 43 starts with the minimum collector-emitter on-voltage 72 of IGBT 1. As the current across IGBT 1 also has to pass some resistance, the voltage drop across IGBT 1 increases with the load current. This produces a slightly sinusoidal curve of the voltage drop across IGBT 1, resulting in a maximum voltage drop 73 at the maximum amplitude of current flowing through the IGBTs. When IGBT 1 is switched off at time 53, the lower voltage drop 74 of the first IGBT 1 switches over to the higher voltage drop 75 of the second IGBT 2. As the load current decreases with time, the voltage drop also decreases down to the minimum collector-emitter on-voltage 76 of IGBT 2 when IGBT 2 is switched off at time 54.

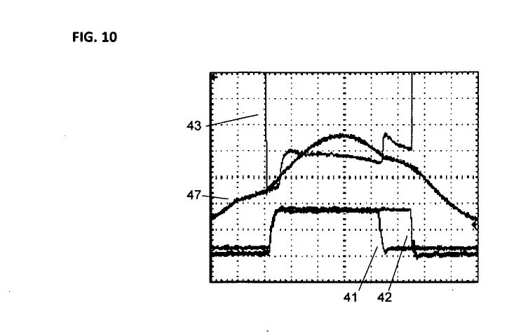

A plot of measurements on a power converter according to FIG. 1 is shown in FIG. 9. This plot is similar to a combination of FIGS. 5 and 6 showing the voltage 34 between the collectors and emitters of IGBTs 1 and 2, together with the load current 33 and the first IGBT gate voltage 21 in curve 41 and the second IGBT gate voltage 22 in curve 42. FIG. 10 is similar to FIG. 9, except for a slightly enlarged timing scale and an enlarged scale of the curve 43, showing details similar to those shown in the curve 43 of FIG. 8.

Embodiments of a power switch described herein comprise at least a first IGBT 1 and a second IGBT 2 coupled in parallel, as shown in FIGS. 1-3. The collectors of the IGBTs are connected together to a common collector line. The emitters of the IGBTs are connected together to a common emitter line in parallel with the common collector line. A control circuit 10 is provided for controlling the gate voltages of the first and the second IGBTs.

In a preferred embodiment, the first IGBT 1 is a type of IGBT with a comparatively low collector-emitter on-voltage and comparatively high switching losses. The second IGBT 2 is a type of IGBT with a comparatively high collector-emitter on-voltage and comparatively low switching losses. In one embodiment, the first IGBT may be of the field-stop (FS) type, while the second IGBT may be of the punch-through (PT), or the non-punch-through (NPT) type. A typical IGBT of the field-stop type is the APT100GN120J manufactured by Advanced Power Technology. A typical punch-through IGBT is the APT75GP120JDQ3 and a typical non-punch-through IGBT is the APT75GT120JRDQ3, both manufactured by Advanced Power Technology. The characteristic technical data of these IGBTs are shown in the table below.

TABLE 1
Characteristic Data of field-stop (FS), punch-through
(PT), and non-punch-through (NPT) IGBTs.

| IGBT Type | FS | | PT | | NPT | |
|---|---|---|---|---|---|---|
| VCEon | 1.7 | V | 3.4 | V | 3.4 | V |
| tr | 50 | ns | 40 | ns | 60 | ns |
| tf | 210 | ns | 110 | ns | 30 | ns |
| td(on) | 50 | ns | 20 | ns | 50 | ns |
| td(off) | 725 | ns | 245 | ns | 415 | ns |
| Eon | 12 | mJ | 1.5 | mJ | 8 | mJ |
| Eoff | 14 | mJ | 5 | mJ | 4 | mJ |

In Table 1, “VCEon” is the collector-emitter on-voltage under nominal load (for example 100 A), “tr” is the current rise time, “tf” is the current fall time, “td(on)” is the turn-on delay time, and “td(off)” is the turn-off delay time of the IGBT. “Eon” is the turn-on switching energy and “Eoff” is the turn-off switching energy of the IGBT.

As shown in FIGS. 1-2, a control circuit 10 is provided for producing the gate control signals 21, 22, which are supplied to the gates of the first and the second IGBTs (1, 2). These gate control signals are referred to the first common emitter line 29. Herein, the term “on-signal” is used to describe a positive voltage which switches the IGBT into a conductive (on) state. The control signals have such timing that the IGBTs switch at different times during an on-time interval. According to the embodiments described herein, the first IGBT 1 having low collector-emitter on-voltage is switched on during times when the load current 33 has its maximum amplitude. These times are typically at the center of the on-time interval. The second IGBT 2 having higher collector-emitter on-voltage, but better switching characteristics, is switched on during the whole on-time interval, thus accomplishing the switching actions, as this IGBT switches on when the on-time interval begins and switches off when the on-time interval ends. However, when the first IGBT 1 is on within the on-time interval, it automatically carries the load current, as it has the lower collector-emitter on-voltage.

This combination of two different IGBTs leads to an improved power switch having the good switching characteristics of the second IGBT and the good conducting characteristics of the first IGBT. Combining the good load characteristics of the IGBTs enables the power switch described herein to switch much higher load currents and load voltages than conventional power switches, which combine an IGBT and a MOSFET. With up to date IGBTs, voltages up to 1200V and currents of up to 400V can be handled in a single SOT-227 case.

Table 1 shows that typical PT and NPT IGBTs have twice the collector-emitter on-voltage (VCEon) rating of the FS IGBT. Accordingly, the FS IGBT can carry the main load current better than a PT or an NPT IGBT. While the current rise times (tr) of all three IGBTs are in a similar range, there are significant differences in the current fall times (tf). While the PT IGBT has about one-half of the current fall time of the FS IGBT, the NPT IGBT has the lowest fall time of all IGBTs. Furthermore, there are significant differences in the turn-on switching energy (Eon) and the turn-off switching energy (Eoff) of the IGBTs. Here, the PT and NPT IGBTs offer best switching performance with lowest switching losses while even the NPT IGBT is better than the FS IGBT.

The wording “comparatively low collector-emitter on-voltage” and “comparatively high collector-emitter on-voltage” is used to specify a difference between the collector-emitter on-voltage rating VCEon of the first IGBT and the second IGBT. For best results, this difference should be more than 20%, preferably 100%. In the example of the above table, there is a 100% difference. Accordingly, there are also differences between the first IGBT and the second IGBT relating to current rise time (tr)/current fall time (tf), or the turn-on switching energy (Eon)/turn-off switching energy (Eoff), of at least 20% or preferably 100%. Furthermore, the second IGBT may be selected with a lower continuous current rating than the first IGBT, as the second IGBT only carries the load current at about the switching time intervals. Therefore, a peak current rating of the second IGBT adapted to the switching currents may be sufficient. This can result in a smaller, and therefore cheaper, second IGBT.

In one preferred embodiment, the on-signal which is supplied to the at least one first IGBT 1 ends at a predetermined first time before the on-signal supplied to the at least one second IGBT 2 ends. This ensures that the first IGBT 1 has already switched off before the second IGBT 2 starts switching off. Preferably, a predetermined first time difference is at least the turn-off time of the first IGBT 1. In calculating this predetermined time difference, also the fall times and/or the turn-off delay times of the first IGBT 1 and/or the second IGBT 2 may be taken into account. Furthermore, this predetermined time difference should be long enough to allow a recombination of the minority carriers in the first IGBT. As the load current is carried by the second IGBT during this recombination time, the losses in the first IGBT are minimized, and primarily the second IGBT determines the switching losses.

As the conducting and switching losses vary with the load conditions, and the recombination time of the charge carriers varies with the temperature, the timing and specifically the predetermined first time difference can be changed by the control circuit (10) in dependence on defined, measured, or calculated parameters like switching frequency, current, or temperature. The control circuit may determine a new predetermined first time difference for each switching cycle.

According to another preferred embodiment, the control circuit 10 is designed to supply an on-signal to the at least one second IGBT 2, and an on-signal to the at least one first IGBT 1, with the on-signal to the at least one first IGBT ending at a predetermined time before the on-signal to the at least one second IGBT 2 ends, and with a predetermined first time difference. This predetermined first time difference is preferably at least the turn-off time of the at least one first IGBT 1. In calculating this predetermined first time difference, also the fall times and/or the turn-off delay times of the first IGBT 1 and/or the second IGBT 2 may be taken into account. Furthermore, this predetermined time difference should be long enough to allow the recombination of the minority carriers in the first IGBT.

In a further embodiment, the on-signal supplied to the at least one first IGBT 1 starts at a predetermined second time after the on-signal to the at least one second IGBT 2 starts, with a second predetermined time difference. In calculating this predetermined second time difference, also the rise times and/or the turn-on delay times of the first IGBT 1 and/or the second IGBT 2 may be taken into account. This ensures that the at least one first IGBT 1 switches on after the at least one second IGBT 2 already has been switched on. This prevents IGBT 1 from taking the full switching load. Also here, the predetermined second time difference can be changed by the control circuit (10) in dependence on defined, measured, or calculated parameters like switching frequency, current, or temperature. The control circuit may determine a new predetermined second time difference for each switching cycle.

In order to obtain the good characteristics described herein, it is essential for the first IGBT 1 to carry the main current load, while the second IGBT 2 performs the switching operation, and for the second IGBT to be switched on first and switched off last. A power converter comprising at least one of the above-mentioned embodiments is also contemplated herein. Such a power converter can be, for example, a switch mode power supply, a drive controller for generating pulsed currents for electric motors, an inverter for a welding apparatus, a solar power inverter, or any other device which uses pulsed electrical signals for electrical energy conversion. Alternatively, the power converter may be a simple hard switching converter. In some cases, the power converter may be based on a resonance circuit, or it may be based on a zero-voltage transition or zero-current switching technology.

A contactless rotary joint having a rotating power transformer and at least one generator for generating pulsed or AC electrical signals from a DC input signal is also contemplated herein. The generator may employ at least one semiconductor power switch according to one of the embodiments disclosed herein. Such a contactless rotary joint may be similar to a switch-mode power supply, where the power transformer is replaced by a rotating transformer.

It will be appreciated to those skilled in the art having the benefit of this disclosure that this invention is believed to provide an improved semiconductor power switch. More specifically, the invention provides a power switch comprising at least one pair of parallel coupled Insulated Gate Bipolar Transistors (IGBTs), wherein the pair of IGBTs includes two different types IGBTs (e.g., one with low collector-emitter on-voltage and high switching losses, and one with high collector-emitter on-voltage and low switching losses). A control circuit is provided for controlling the activation/deactivation of the IGBTs, so as to combine the good characteristics of the different types of IGBTs. Further modifications and alternative embodiments of various aspects of the invention will be apparent to those skilled in the art in view of this description. It is intended, therefore, that the following claims be interpreted to embrace all such modifications and changes and, accordingly, the specification and drawings are to be regarded in an illustrative rather than a restrictive sense.

1. A semiconductor power switch, comprising:
a first pair of IGBTs including a first IGBT having a collector and an emitter and a second IGBT having a collector and an emitter, wherein the collectors of the first and second IGBTs are directly connected to each other, and the emitters of the first and second IGBTs are directly connected to each other;
a control circuit for supplying gate signals to the IGBTs for switching on the power switch during a first time interval, and switching off the power switch during a second time interval;
wherein the first IGBT is of an IGBT type with a comparatively low collector-emitter on-voltage and a comparatively high turn-on or turn-off switching energy;
wherein the second IGBT is of an IGBT type with a comparatively high collector-emitter on-voltage and a comparatively low turn-on or turn-off switching energy; and
wherein the control circuit supplies an on-signal to a gate of the second IGBT during a whole of the first time interval, and another on-signal to a gate of the first IGBT during only a part of the first time interval, which is less than the whole.

2. The power switch according to claim 1, wherein the on-signal supplied to the first IGBT ends before the on-signal supplied to the second IGBT ends, with a predetermined first time difference which is at least a turn-off time of the first IGBT.

3. The power switch according to claim 2, wherein the predetermined first time difference is set according to an estimated, measured, or preset load condition selected from a group comprising: load current, switching frequency, and temperature.

4. The power switch according to claim 1, wherein the on-signal supplied to the first IGBT starts after the on-signal supplied to the second IGBT starts, with a predetermined second time difference which is at least a turn-on time of the second IGBT.

5. The power switch according to claim 4, wherein the predetermined second time difference is set according to an estimated, measured, or preset load condition selected from a group comprising: load current, switching frequency, and temperature.

6. The power switch according to claim 1, further comprising:
a second pair of IGBTs including a third IGBT having a collector and an emitter and a fourth IGBT having a collector and an emitter, wherein the collectors of the third and fourth IGBTs are directly connected to each other, and the emitters of the third and fourth IGBTs are directly connected to each other;
wherein the third IGBT is of an IGBT type with a comparatively low collector-emitter on-voltage and a comparatively high turn-on or turn-off switching energy;
wherein the fourth IGBT is of an IGBT type with a comparatively high collector-emitter on-voltage and a comparatively low turn-on or turn-off switching energy; and
wherein the mutually connected emitters of the first pair of IGBTs are connected to the mutually connected collectors of the second pair of IGBTs along a common line.

7. The power switch according to claim 6, further comprising:
a pair of serially coupled diodes connected in parallel with the first and second pair of IGBTs, wherein a polarity of the diodes is opposite to a current flow through the first and second pairs of IGBTs;
a DC power source connected in parallel with the first and second pair of IGBTs; and
a resonant load circuit coupled in series with the common line between the pair of diodes and the DC power source for providing a load current to the common line.

8. The power switch according to claim 7, wherein during positive half waves of the load current, the control circuit supplies gate signals to the second pair of IGBTs for placing the second pair in a high impedance state, and gate signals to the first pair of IGBTs for placing the first pair in a conducting state for switching the power switch on during the first time interval.

9. The power switch according to claim 7, wherein during negative half waves of the load current, the control circuit supplies gate signals to the first pair of IGBTs for placing the first pair in a high impedance state, and gate signals to the second pair of IGBTs for placing the second pair in a conducting state for switching the power switch on during the first time interval.

10. A semiconductor power switch, comprising:
a first IGBT having a collector and an emitter;
a second IGBT having a collector and an emitter, wherein the collectors of the IGBTs are directly connected to each other, and the emitters of the IGBTs are directly connected to each other;
a control circuit for supplying gate signals to the IGBTs for switching on the power switch during a first time interval, and switching off the power switch during a second time interval;
wherein the first IGBT is of an IGBT type with a comparatively low collector-emitter on-voltage and a comparatively high turn-on or turn-off switching energy;
wherein the second IGBT is of an IGBT type with a comparatively high collector-emitter on-voltage and a comparatively low turn-on or turn-off switching energy; and
wherein the control circuit supplies an on-signal to a gate of the second IGBT and another on-signal to a gate of the first IGBT, wherein the on-signal supplied to the first IGBT ends before the on-signal supplied to the second IGBT ends, with a predetermined first time difference which is at least the turn-off time of the first IGBT.

11. The power switch according to claim 10, wherein the predetermined first time difference is set according to an estimated, measured, or preset load condition selected from a group comprising: load current, switching frequency, and temperature.

12. The power switch according to claim 10, wherein the on-signal supplied to the first IGBT starts after the on-signal supplied to the second IGBT starts, with a predetermined second time difference which is at least a turn-on time of the second IGBT.

13. The power switch according to claim 12, wherein the predetermined second time difference is set according to an estimated, measured, or preset load condition selected from a group comprising: load current, switching frequency, and temperature.

14. A power converter for generating an AC signal which can be coupled via a transformer, wherein the power converter includes a semiconductor power switch comprising:
a first IGBT having a collector and an emitter;
a second IGBT having a collector and an emitter, wherein the collectors of the IGBTs are directly connected to each other, and the emitters of the IGBTs are directly connected to each other;
a control circuit for supplying gate signals to the IGBTs for switching on the power switch during a first time interval, and switching off the power switch during a second time interval;
wherein the first IGBT is of an IGBT type with a comparatively low collector-emitter on-voltage and a comparatively high turn-on or turn-off switching energy;
wherein the second IGBT is of an IGBT type with a comparatively high collector-emitter on-voltage and a comparatively low turn-on or turn-off switching energy; and
wherein the control circuit supplies an on-signal to a gate of the second IGBT during a whole of the first time interval, and another on-signal to a gate of the first IGBT during only a part of the first time interval, which is less than the whole.

15. A power converter for generating an AC signal which can be coupled via a transformer, wherein the power converter includes a semiconductor power switch comprising:
a first IGBT having a collector and an emitter;
a second IGBT having a collector and an emitter, wherein the collectors of the IGBTs are directly connected to each other, and the emitters of the IGBTs are directly connected to each other;
a control circuit for supplying gate signals to the IGBTs for switching on the power switch during a first time interval, and switching off the power switch during a second time interval;
wherein the first IGBT is of an IGBT type with a comparatively low collector-emitter on-voltage and a comparatively high turn-on or turn-off switching energy;
wherein the second IGBT is of an IGBT type with a comparatively high collector-emitter on-voltage and a comparatively low turn-on or turn-off switching energy; and
wherein the control circuit supplies an on-signal to a gate of the second IGBT and another on-signal to a gate of the first IGBT, wherein the on-signal supplied to the gate of the first IGBT ends before the on-signal supplied to the gate of the second IGBT ends, with a predetermined first time difference which is at least a turn-off time of the first IGBT.

16. A contactless rotary joint having a rotating power transformer and a semiconductor power switch for generating an AC signal which can be coupled via a transformer, the power switch comprising:
a first IGBT having a collector and an emitter;
a second IGBT having a collector and an emitter, wherein the collectors of the IGBTs are directly connected to each other, and the emitters of the IGBTs are directly connected to each other;
a control circuit for supplying gate signals to the IGBTs for switching on the power switch during a first time interval, and switching off the power switch during a second time interval;
wherein the first IGBT is of an IGBT type with a comparatively low collector-emitter on-voltage and a comparatively high turn-on or turn-off switching energy;
wherein the second IGBT is of an IGBT type with a comparatively high collector-emitter on-voltage and a comparatively low turn-on or turn-off switching energy; and
wherein the control circuit supplies an on-signal to a gate of the second IGBT during a whole of the first time interval, and another on-signal to a gate of the first IGBT during only a part of the first time interval, which is less than the whole.

17. A contactless rotary joint having a rotating power transformer and a semiconductor power switch for generating an AC signal which can be coupled via a transformer, the power switch comprising:
a first IGBT having a collector and an emitter;
a second IGBT having a collector and an emitter, wherein the collectors of the IGBTs are directly connected to each other, and the emitters of the IGBTs are directly connected to each other;
a control circuit for supplying gate signals to the IGBTs for switching on the power switch during a first time interval, and switching off the power switch during a second time interval;
wherein the first IGBT is of an IGBT type with a comparatively low collector-emitter on-voltage and a comparatively high turn-on or turn-off switching energy;
wherein the second IGBT is of an IGBT type with a comparatively high collector-emitter on-voltage and a comparatively low turn-on or turn-off switching energy; and
wherein the control circuit supplies an on-signal to a gate of the second IGBT and another on-signal to a gate of the first IGBT, wherein the on-signal supplied to the first IGBT ends at a time before the on-signal supplied to the second IGBT ends, with a predetermined first time difference which is at least a turn-off time of the first IGBT.
